(19) United States
(12) Patent Application Publication
(10) Pub. No.: US 2008/0117604 A1
(43) Pub. Date: May 22, 2008

(54) MOUNTING APPARATUS FOR MOTHERBOARD

(75) Inventors: KE SUN, Shenzhen (CN); MING-KE CHEN, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/765,457

(22) Filed: Jun. 20, 2007

(30) Foreign Application Priority Data
Nov. 16, 2006 (CN) 200610201103.X

(51) Int. Cl. H05K 7/00

(52) U.S. Cl. 361/748

(57) ABSTRACT

A mounting apparatus for fixing a motherboard having a plurality of fixing holes defined therein. The motherboard includes a first face and a second face; the mounting apparatus includes a supporting stage and a plurality of fixing poles. The supporting stage includes a first supporting surface and a second supporting surface; a plurality of first fixing portions is formed on the first supporting surface for aligning with the corresponding fixing holes of the motherboard. A plurality of second fixing portions is also formed on the second supporting surface for aligning with the corresponding fixing holes of the motherboard when the motherboard is inverted. One end of each of the fixing poles engages with a corresponding second fixing portion of the second supporting surface, and the other end of each of the fixing poles aligns with a corresponding fixing hole of the motherboard when the motherboard is inverted.

### BACKGROUND OF THE INVENTION

1. Field of the Invention

The present invention relates to mounting apparatuses for motherboards, and more particularly to a mounting apparatus for mounting a motherboard thereon.

2. Description of Related Art

Typically, a motherboard needs to be installed on a mounting apparatus when tested during development or manufacture. The motherboard includes two faces, with a plurality of electronic components installed on one face of the motherboard, and a plurality of fixing holes defined in the motherboard. The mounting apparatus typically includes a base, and a plurality of protrusions formed on the base corresponding to the fixing holes of the motherboard. Each protrusion of the mounting apparatus defines a threaded hole in a top portion thereof. The motherboard is placed on the protrusions with the face having the electronic components mounted thereon facing up, and a plurality of screws extends through the fixing holes of the motherboard respectively and engages in the threaded holes of the corresponding protrusions, thereby the motherboard is fixed to the mounting apparatus. However, it may be needful to test both faces of the motherboard, but the typical mounting apparatus cannot support the face of the motherboard on which the electronic components are mounted, because the electronic components will interfere with and be damaged by the mounting apparatus when the motherboard is invertedly supported on the mounting apparatus.

What is needed, therefore, is a mounting apparatus which is capable of mounting a motherboard thereon without interference with electronic components of the motherboard.

### SUMMARY OF THE INVENTION

A mounting apparatus is supplied for fixing a motherboard having a plurality of fixing holes defined therein. The motherboard includes a first face and a second face; the mounting apparatus includes a supporting stage and a plurality of fixing poles. The supporting stage includes a first supporting surface and a second supporting surface; a plurality of first fixing portions is formed on the first supporting surface for aligning with the corresponding fixing holes of the motherboard. A plurality of second fixing portions is also formed on the second supporting surface for aligning with the corresponding fixing holes of the motherboard when the motherboard is inverted. One end of each of the fixing poles engages with a corresponding second fixing portion of the second supporting surface, and the other end of each of the fixing poles aligns with a corresponding fixing hole of the motherboard when the motherboard is inverted.

Other advantages and novel features will become more apparent from the following detailed description of preferred embodiment when taken in conjunction with the accompanying drawings, in which:

### BRIEF DESCRIPTION OF THE DRAWINGS

FIG. 1 is a partially exploded, isometric view of a mounting apparatus together with a motherboard in accordance with a preferred embodiment of the present invention, the mounting apparatus being in a first using state;

FIG. 2 is an assembled view of FIG. 1;

FIG. 3 is a partially exploded, isometric view of the mounting apparatus, the mounting apparatus being turned upside down and in a second using state;

FIG. 4 is an assembled view of FIG. 3; and

FIG. 5 shows the mounting apparatus supporting the motherboard in an inverted position.

### DETAILED DESCRIPTION OF THE INVENTION

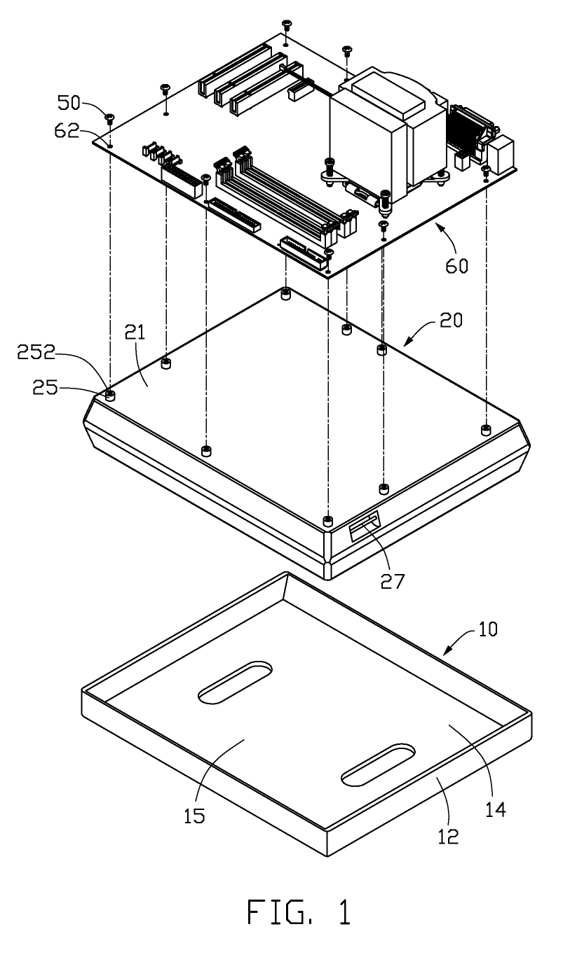

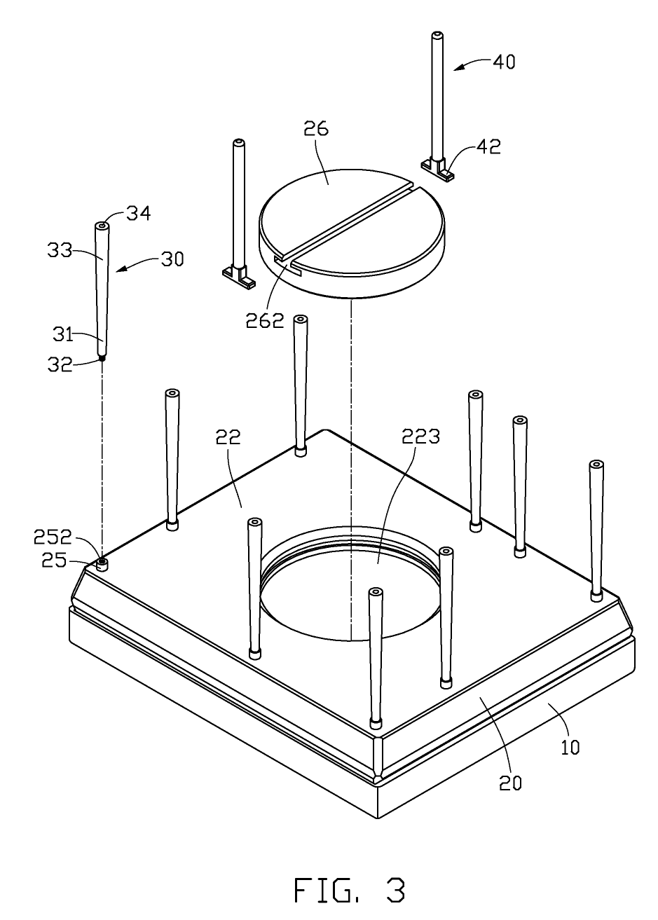

Referring to FIGS. 1 and 3, a mounting apparatus is provided in accordance with an embodiment of the present invention, for fixing a motherboard 60 having a plurality of fixing holes 62 defined therein. The mounting apparatus includes a base 10, a supporting stage 20, a plurality of fixing poles 30, two supporting posts 40, and a plurality of fasteners, such as screws 50. In this embodiment, a plurality of electronic components is installed on a first face of the motherboard 60.

The base 10 includes four sidewalls 12, and a bottom wall 14. A receiving space 15 is formed between the sidewalls 12 and the bottom wall 14, for receiving the supporting stage 20 therein.

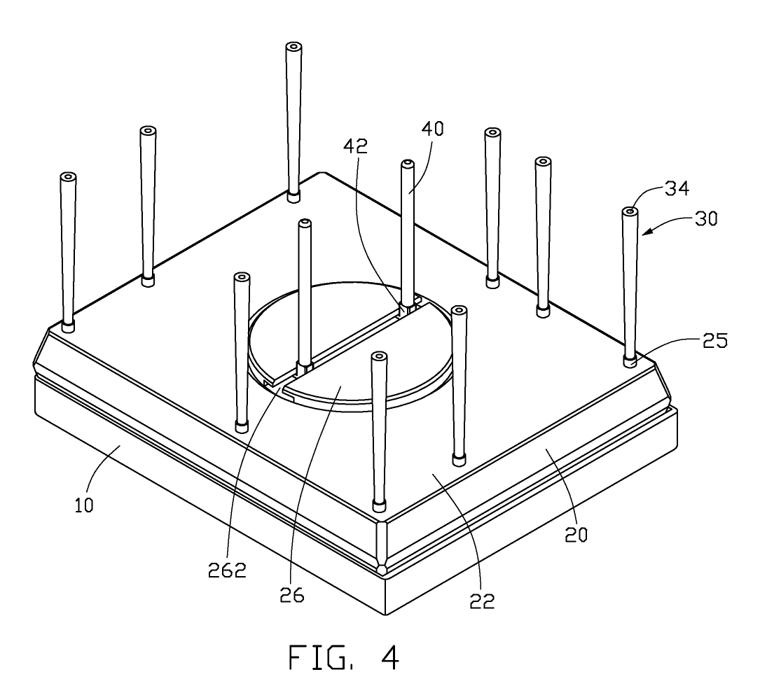

The supporting stage 20 includes a first supporting surface 21, a second supporting surface 22, and a circular plate 26 rotatably mounted on the second supporting surface 22. A plurality of fixing portions 25 protrudes from the first supporting surface 21 corresponding to the fixing holes 62 of the motherboard 60, for supporting a second face of the motherboard 60. A plurality of fixing portions 25 protrudes from the second supporting surface 22 and are so arranged to align with the fixing holes 62 of the motherboard 60 after the motherboard 60 is inverted. Each fixing portion 25 defines a threaded hole 252 therein. A circular recess 223 is defined in a middle section of the second supporting surface 22 for receiving the circular plate 26. An inverted T-shaped slot 262 is defined bisecting a top portion of the circular plate 26. The height of the circular plate 26 is greater than the depth of the circular recess 223, when the circular plate 26 is placed on the circular recess 223 of the second supporting surface 22, the top portion of the circular plate 26 is exposed from the circular recess 223, and two ends of the slot 262 are located generally above the second supporting surface 22 (see FIG. 4). Referring particularly to FIG. 1, a grounded anti-static rod 27 is installed in a lateral side of the supporting stage 20.

Referring to FIG. 3, each fixing pole 30 is placed in alignment with one of the corresponding fixing holes 62 of the motherboard 60 and includes a first end 31 and a second end 33. A threaded protrusion 32 extends from each of the first ends 31, for engaging in the threaded hole 252 of the corresponding fixing portion 25 of the supporting stage 20. A threaded hole 34 is defined in each of the second ends 33, for receiving one of the fasteners 50 passed through the corresponding fixing hole 62 of the motherboard 60 after the motherboard 60 is inverted.

An inverted T-shaped foot 42 is fixed on an end of each supporting post 40, corresponding to the slot 262 of the circular plate 26.

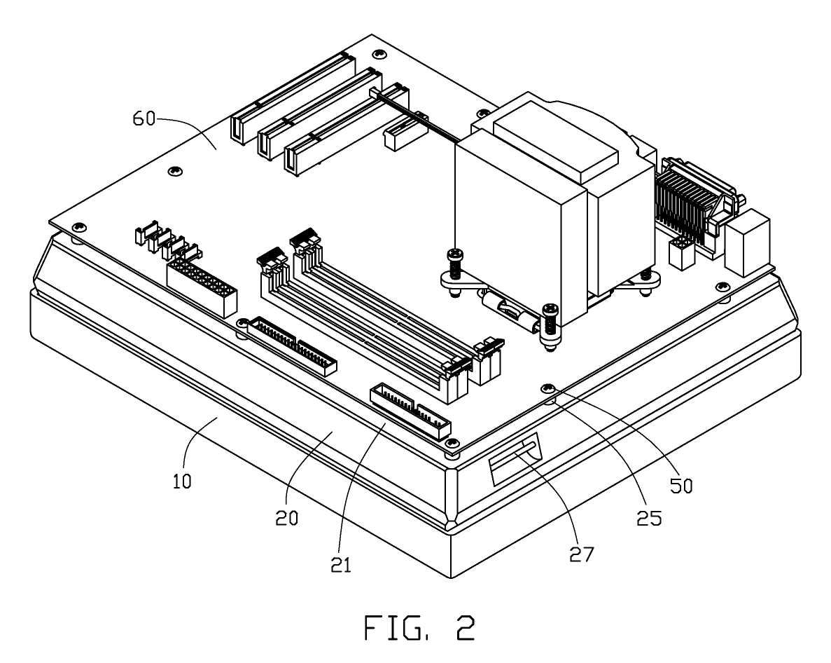

Referring also to FIGS. 1 and 2, to mount the motherboard 60 on the supporting stage 20 with the electronic components facing upward, the supporting stage 20 is received in the receiving space 15 of the base 10 with the first supporting surface 21 facing upward. The motherboard 60 is placed on the fixing portions 25 of the first supporting surface 21 of the supporting stage 20, with the electronic components facing upward, and with the fixing holes 62 of the motherboard 60 in alignment with the threaded holes 252 of the fixing portions 25 of the first supporting surface 21 respectively. The screws 50 extend through the fixing holes 62 of the motherboard 60 respectively, and are screwed into the corresponding threaded holes 252, thereby the motherboard 60 is fixed on the supporting stage 20 with the electronic components facing upward.

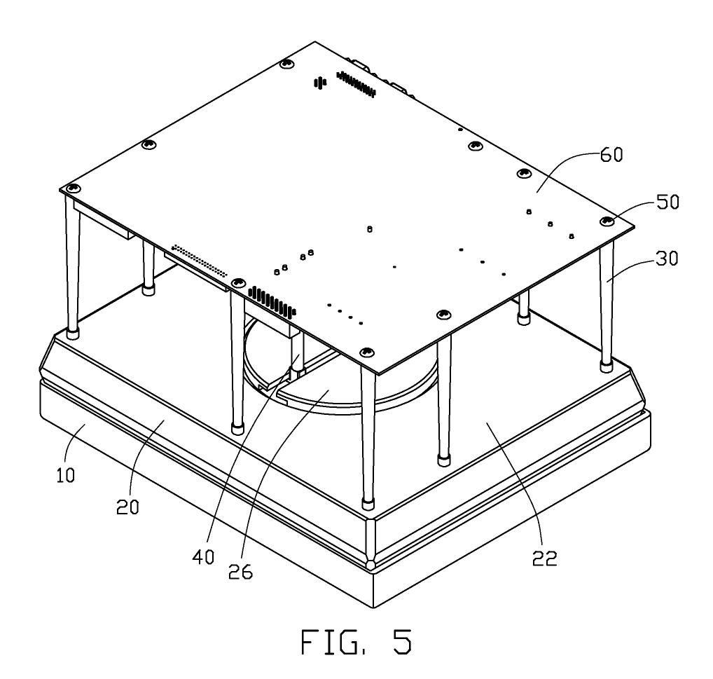

Referring further to FIGS. 3 to 5, to support the motherboard 60 on the supporting stage 20 in an inverted position, the supporting stage 20 is turned upside down and received in the receiving space 15 of the base 10 with the second supporting surface 22 facing upward, and the circular plate 26 received in the circular recess 223 of the second supporting surface 22. The foots 42 of the supporting posts 40 are slidably received in the slot 262 of the circular plate 26, thereby the supporting posts 40 are slidably supported in the slot 262. The threaded protrusions 32 of the first ends 31 of the fixing poles 30 are engaged in the threaded holes 252 of the fixing portions 25 of the second supporting surface 22 respectively, thereby the fixing poles 30 are fixed to the supporting stage 20, and the top portions of the fixing poles 30 and the supporting posts 40 are located at a same level, thereby cooperatively forming a horizontal fixing plane. The motherboard 60 is inverted and placed on the fixing plane formed by the fixing poles 30 and the supporting posts 40, with the fixing holes 62 of the inverted motherboard 60 aligning with the threaded holes 34 of the second ends 33 of the fixing poles 30 respectively. In this process, to achieve alignment of the fixing poles 30 with the fixing holes 62 of the motherboard 60 and avoid the supporting posts 40 interfering with and damaging the electronic components mounted on the motherboard 60, the circular plate 26 in the supporting stage 20 may be rotated within the circular recess 223, and the supporting posts 40 slid to a desired position in the slot 262 of the circular plate 26 to support the motherboard 60 via abutting against areas where no electronic component is mounted. The screws 50 extend through the fixing holes 62 of the motherboard 60 respectively and are received in the threaded holes 34 of the corresponding fixing poles 30, thereby the motherboard 60 is inversely mounted on the supporting stage 20.

It is believed that the present embodiment and its advantages will be understood from the foregoing description, and it will be apparent that various changes may be made thereto without departing from the spirit and scope of the invention or sacrificing all of its material advantages, the example hereinbefore described merely being preferred or exemplary embodiment of the invention.

What is claimed is:

1. A mounting apparatus for fixing a motherboard having a plurality of fixing holes defined therein, the motherboard comprising a first face and a second face, the mounting apparatus comprising:
a supporting stage comprising a first supporting surface and a second supporting surface, a plurality of first fixing portions formed on the first supporting surface configured for aligning with the corresponding fixing holes of the motherboard and supporting the second face of the motherboard, a plurality of second fixing portions being so formed on the second supporting surface for aligning with the corresponding fixing holes of the motherboard when the motherboard is inverted; and
a plurality of fixing poles, one end of each of the fixing poles configured for engaging with a corresponding second fixing portion of the second supporting surface respectively, and the other end of each of the fixing poles configured for aligning with a corresponding fixing hole of the motherboard and supporting the first face of the motherboard when the motherboard is inverted.

2. The mounting apparatus as claimed in claim 1, wherein each of the second fixing portions defines a threaded hole therein, a threaded protrusion extends from said one end of each of the fixing poles for engaging in the corresponding threaded hole of the second fixing portion of the second supporting surface.

3. The mounting apparatus as claimed in claim 1, wherein said the other end of each of the fixing poles defines a threaded hole, a plurality of fasteners is provided for extending through the fixing holes of the motherboard respectively and engaging in the threaded holes of the corresponding fixing holes.

4. The mounting apparatus as claimed in claim 1, further comprising at least one supporting post, wherein the second supporting surface of the supporting stage defines a circular recess therein, the supporting stage further comprises a circular plate rotatably received in the circular recess, a top portion of the circular plate defines a bisecting slot, and the supporting post is slidably supported in the slot for supporting the motherboard.

5. The mounting apparatus as claimed in claim 4, wherein the slot has an inverted T-shaped cross-section, an inverted T-shaped foot is fixed on an end of the supporting post for slidably engaging in the slot.

6. The mounting apparatus as claimed in claim 4, wherein the height of the circular plate is greater than the depth of the circular recess such that two ends of the slot are located above the second supporting surface when the circular plate is received in the supporting stage.

7. The mounting apparatus as claimed in claim 1, further comprising a base defining a receiving space therein for receiving the supporting stage.

8. The mounting apparatus as claimed in claim 1, wherein a grounded anti-static rod is installed in the supporting stage.

9. A mounting apparatus for a motherboard, the mounting apparatus comprising:
a supporting stage comprising a supporting surface and a circular plate rotatably mounted on the supporting surface, a top portion of the circular plate defines a bisecting slot; and
at least one supporting post slidably engaged in the slot of the circular plate for supporting the motherboard thereon.

10. The mounting apparatus as claimed in claim 9, wherein a plurality of fixing portions is formed on the supporting surface configured for aligning with corresponding fixing holes of the motherboard, the mounting apparatus further comprises a plurality of fixing poles, one end of each of the fixing poles is configured for engaging with a corresponding fixing portion of the supporting surface respectively, and the other end of each of the fixing poles is configured for aligning with one of the fixing holes of the motherboard.

11. The mounting apparatus as claimed in claim 10, wherein each of the fixing portions defines a threaded hole therein, a threaded protrusion extends from said one end of each of the fixing poles for engaging in the corresponding threaded hole of the fixing portion of the supporting surface.

12. The mounting apparatus as claimed in claim 10, wherein said the other end of each of the fixing poles defines a threaded hole, a plurality of fasteners is provided for extending through the fixing holes of the motherboard respectively and engaging in the threaded holes of the corresponding fixing holes.

13. The mounting apparatus as claimed in claim 9, wherein the slot in the circular plate has an inverted T-shaped cross-section, an inverted T-shaped foot is fixed on an end of the supporting post for slidably engaging in the slot.

14. The mounting apparatus as claimed in claim 9, wherein the circular plate is higher than the supporting surface, the slot is defined in the circular plate from one end to another end of the top portion thereof, and two ends of the slot are located above the supporting surface of the supporting stage.
